(19) United States
(12) Patent Application Publication
(10) Pub. No.: US 2021/0165947 A1
(43) Pub. Date: Jun. 3, 2021

(54) INTEGRATED CIRCUITS INCLUDING STANDARD CELL STRUCTURES AND LAYOUT METHODS

(71) Applicant: Samsung Electronics Co., Ltd., Suwon-si (KR)

(72) Inventors: JAE-HO PARK, Suwon-si (KR); SANGHOON BAEK, Seoul (KR); JI SU YU, Seoul (KR); HYEON GYU YOU, Hwaseong-si (KR); SEUNG YOUNG LEE, Seoul (KR); SEUNG MAN LIM, Siheung-si (KR); MIN JAE JEONG, Gwangju (KR); JONG HOON JUNG, Seongnam-si (KR)

(21) Appl. No.: 17/087,915

(22) Filed: Nov. 3, 2020

(30) Foreign Application Priority Data
Nov. 29, 2019 (KR) 10-2019-0156559
Jun. 16, 2020 (KR) 10-2020-0073127

(51) Int. Cl. G06F 30/392; H01L 27/02; G06F 30/394

(52) U.S. Cl. CPC G06F 30/392; G06F 30/394; H01L 27/0207

(57) ABSTRACT

A layout method is provided. The layout method may include placing first and second standard cells from a standard cell library, interconnecting the placed standard cells to generate a layout draft, confirming placement and routing at a boundary region between the interconnected standard cells, and revising the layout draft based on the confirmation. Each of the standard cells includes, in part, a conductive line that extends in the first direction and is interconnected to an adjacent standard cell through a source/drain via. To confirm the placement and routing, a first spaced distance from a tip of one of the conductive lines to a tip of the other conductive line, and a second spaced distance from the tip of the first conductive line to the cell boundary are compared with preset threshold values. Revising the layout draft may include adjusting a tip position of one of the conductive lines.

### CROSS-REFERENCE TO RELATED APPLICATIONS

This application claims the benefit of priority under 35 U.S.C. § 119 to Korean Patent Application No. 10-2019-0156559 filed on Nov. 29, 2019, and to Korean Patent Application No. 10-2020-0073127 filed on Jun. 16, 2020, both filed in the Korean Intellectual Property Office, the contents of each of which are herein incorporated by reference in their entireties.

### BACKGROUND

### 1. Technical Field

The present disclosure relates to layout methods of integrated circuits including integrated standard cell structures.

### 2. Description of the Related Art

Integrated circuits may be designed on the basis of standard cells. Specifically, layouts of integrated circuits may be generated by placing standard cells according to data defining the integrated circuits and by routing the placed standard cells. Standard cells may be predesigned and stored in a cell library.

With the miniaturization of semiconductor fabricating processes, sizes of patterns in each of the standard cells may decrease, and size of the standard cells themselves may also decrease.

### SUMMARY

Some aspects of the present disclosure may provide layout methods of integrated circuits having layouts which may be used in miniaturized semiconductor fabrication processes due to patterns of simple or more simplified structures.

Some aspects of the present disclosure may also provide layout methods of integrated circuits having improved operational reliability due to the layout of the simplified structures.

Some aspects of the present disclosure may provide, as an example, a layout method of an integrated circuit including standard cells, the layout method comprising placing first and second standard cells selected from a standard cell library, interconnecting the placed first and second standard cells to generate a layout draft, confirming placement and routing at a boundary region between the interconnected first and second standard cells and revising the layout draft as a result of the confirmation. Each of the standard cells may include an active region that extends in a first direction, a gate line that extends in a second direction and that intersects the active region, a source/drain region that extends in the second direction and is placed on one side of the gate line, a source/drain via placed on the source/drain region and a conductive line that extends in the first direction and is interconnected to an adjacent standard cell through the source/drain via. Confirming the placement and routing may include comparing a first spaced distance from a tip of a first conductive line of the first standard cell to a tip of a second conductive line of the second standard cell, and a second spaced distance from the tip of the first conductive line of the first standard cell to the cell boundary with first and second preset threshold values, respectively, and revising the layout draft may include adjusting, a tip position of the conductive line of the second standard cell.

Some aspects of the present disclosure may provide, as an example, a layout method of an integrated circuit, the layout method comprising steps of placing a first standard cell and a second standard cell from a standard cell library on respective sides of a cell boundary, placing a source/drain via and a conductive line on each of the first standard cell and the second standard cell, measuring a first spaced distance between a tip of the conductive line of the first standard cell and measuring a second spaced distance between a tip of the conductive line of the second standard cell and the cell boundary, adjusting a tip position of the tip of the conductive line of the first standard cell or a tip position of the tip of the conductive line of the second standard cell when the first spaced distance or the second spaced distance is equal to or greater than a preset threshold value and settling a layout at the of the conductive line having the adjusted tip position.

Some aspects of the present disclosure may provide, as an example, an integrated circuit that includes a first standard cell and a second standard cell adjacent to each other in a first direction. The first standard cell comprises, a first gate line that extends in a second direction, a first source/drain region that extends in the second direction and is placed on one side of the first gate line, a first source/drain via that is placed on the first source/drain region and a first conductive line that extends in the first direction and is placed to be connected to an upper surface of the first source/drain via, The second standard cell comprises, a second gate line that extends in the second direction, a second source/drain region that extends in the second direction and is placed between the second gate line and a cell boundary with the first standard cell, a second source/drain via that is placed on the second source/drain region and a second conductive line that extends in the first direction and is placed to be connected to an upper surface of the second source/drain via. When a spaced distance between a tip of the first conductive line facing the cell boundary and a tip of the second conductive line facing the cell boundary is equal to or greater than a preset threshold value, a length in the first direction from the tip of the first conductive line to an intersection of the first conductive line with the first source/drain via has a length different from a preset first width.

Aspects of the present disclosure are not limited to the those explicitly set forth above, and other aspects of the present disclosure will become more apparent to those of ordinary skill in the art to which the present disclosure pertains upon thorough review of the detailed description of the present inventive concepts given below.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a flowchart showing operations of methods for fabricating integrated circuits that include one or more of a plurality of standard cells, according to some example embodiments.

FIG. 2 is a diagram showing aspects of a layout of an example integrated circuit, according to some example embodiments.

FIG. 3 is a diagram showing a cross section of the example integrated circuit of FIG. 2.

FIGS. 4 and 5 show layouts of the example integrated circuit according to some example embodiments.

FIGS. 6 to 8 show layouts of the example integrated circuit according to some example embodiments.

FIG. 9 is a block diagram showing an example of a computing system that includes a memory that stores a program, according to some example embodiments.

### DETAILED DESCRIPTION

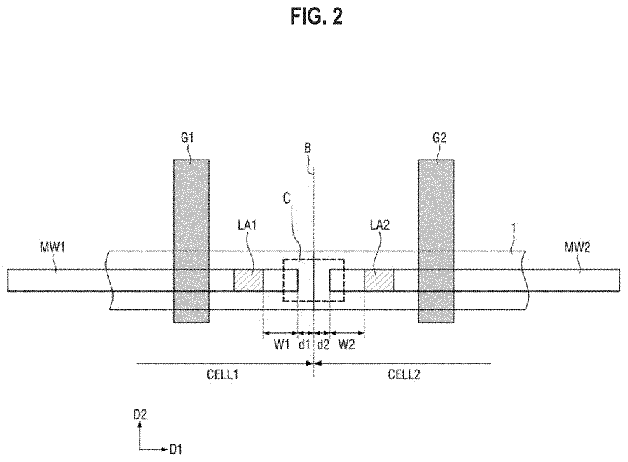

In the following explanation, integrated circuits of various example embodiments are provided. An integrated circuit may be formed on a substrate (e.g., substrate 1 of FIG. 2), for example, a semiconductor substrate. The integrated circuit has a layout that includes various standard cells. The standard cells are integrated circuit structures that are predesigned for repeated use in the design of individual integrated circuits. Effective integrated circuit design layouts include various pre-designed standard cells and pre-defined rules related to placement of standard cells to enhance circuit performance and reduce a circuit area. In some instances, the pre-defined rules may be related to various aspects of a fabrication process for the integrated circuits.

The integrated circuit according to some example embodiments includes one or more standard cells placed in the integrated circuit layout by the pre-defined rules. Such standard cells are used repeatedly in the design of integrated circuits. Therefore, the standard cells are pre-designed according to fabricating technology, and stored in the standard cell library. An integrated circuit designer may search for such standard cells, include them in the integrated circuit design, and place them in the integrated circuit layout according to a pre-defined placement rules.

The standard cell may include various basic circuit devices (e.g., logic gates), like an inverter, an AND, a NAND, an OR, a XOR, and a NOR, which may be frequently used in the digital circuit design of electronic devices. Examples of electronic devices include central processing units (CPU), graphic processing units (GPU), and system-on-chip (SOC) designs. Standard cells may include other devices frequently used in circuit blocks, such as a flip-flop and a latch.

A standard cell according to some example embodiments may be included in each functional block of a System On Chip (SoC) to improve integration and improve performance and reliability of a designed SoC.

Hereinafter, embodiments according to the present inventive concepts will be described with reference to the accompanying drawings.

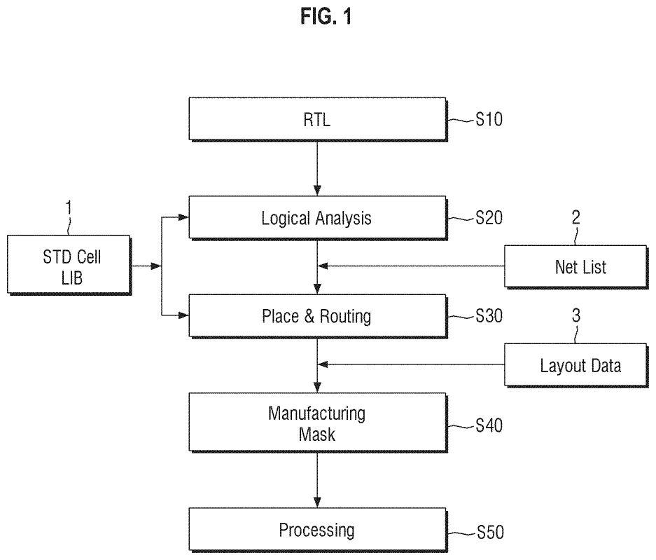

FIG. 1 is a flowchart showing operations of methods for fabricating integrated circuits that include one or more of a plurality of standard cells, according to some example embodiments.

A standard cell library 1 may include information on a plurality of standard cells, for example, functional information, characteristic information, layout information and the like.

In step S20, a logic synthesis operation for generating netlist data 2 from register-transfer level (RTL) data S10 may be performed. For example, a semiconductor design tool (e.g., a logic synthesis tool) may generate data 2 including a bitstream or a netlist, by performing a logic synthesis from RTL data S10 created as a VHDL (VHSIC Hardware Description Language) and a HDL (Hardware Description Language) such as Verilog, with reference to the standard cell library 1.

In step S30, a Place & Routing (P & R) operation for generating the layout data 3 from the netlist data 2 may be performed. The place & routing step S30 may include a plurality of steps.

According to some example embodiments, the place & routing step S30 may include performing an operation of selectively placing the standard cells. A semiconductor design tool (e.g., the P&R tool) may place a plurality of standard cells from the netlist data 2 with reference to the standard cell library 1.

According to some embodiments, the place & routing step S30 may include performing an operation of generating an interconnection. The interconnection may electrically connect an output fin and an input fin of the standard cell, and may include, for example, at least one via and at least one conductive pattern. By generating the interconnection, the standard cells may be routed.

According to some example embodiments, the place & routing step S30 may include performing an operation of generating a layout draft of the layout data 3. The layout data 3 may have a format such as a Graphic Design System II (GDSII) format, and may include geometric information of the standard cells and interconnections.

According to some example embodiments, the place & routing step S30 may include checking portions to be revised in the layout draft to make revisions on the interconnections. The revised layout data may be finally settled.

In step S40, an operation of manufacturing a mask may be performed. For example, a pattern formed on a plurality of layers may be defined according to the layout data 3, and at least one mask (or photomask) for forming patterns of each of the plurality of layers may be manufactured.

In step S50, an operation of fabricating an integrated circuit may be performed. For example, the integrated circuit may be fabricated, by patterning a plurality of layers, using at least one mask manufactured in step S40.

According to some example embodiments, a front-end-of-line (FEOL) process may be performed in step S50. The FEOL process may refer to a process of forming individual elements for example, transistors, capacitors, and resistors, on a substrate in a process of fabricating the integrated circuit. For example, the FEOL process may include a step of planarizing and cleaning a wafer, a step of forming a trench, a step of forming a well, a step of forming a gate line, a step of forming a source and a drain, and the like.

A BEOL (back-end-of-line) process may be performed in step S50 according to some example embodiments. The BEOL process may refer to a process of connecting individual elements, for example, transistors, capacitors, and resistors to each other in a process of fabricating the integrated circuit. For example, the BEOL process may include a step of silicidation of a gate, a source and a drain region, a step of adding a dielectric, a planarizing step, a step of forming holes, a step of adding a metal layer, a step of forming a via, a step of forming a passivation layer and the like. Thereafter, the integrated circuit may be packaged in a semiconductor package and used as a component of various applications.

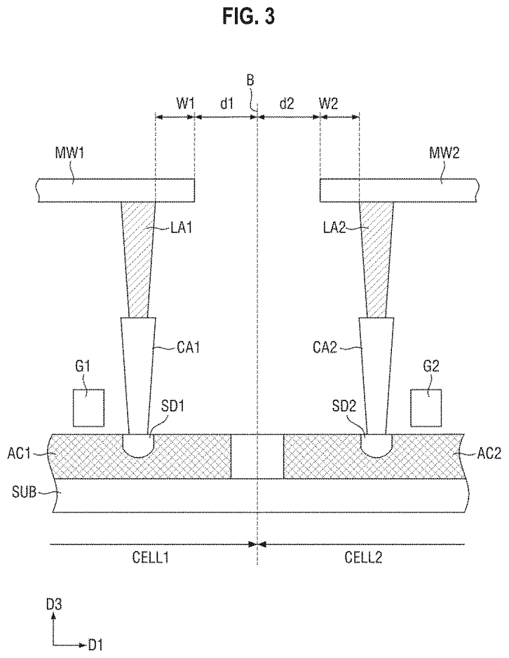

FIG. 2 is a diagram showing aspects of a layout of an example integrated circuit according to some example embodiments, and FIG. 3 is a diagram showing a cross section of the example integrated circuit of FIG. 2.

Referring to FIGS. 2 and 3, an active pattern AC may extend in a first direction D1 on a substrate SUB having a plane parallel to a horizontal plane. The active pattern AC may include semiconductors such as silicon (Si) or germanium (Ge), or compound semiconductors such as silicon-germanium (SiGe), silicon carbide (SiC), gallium arsenide (GaAs), indium arsenide (InAs) and indium phosphide (InP). The active pattern AC may include a conductive region, for example, an impurity-doped well, and an impurity-doped structure.

The active pattern AC may be separated into a first active region AC1 and a second active region AC2. The active regions AC1 and AC2 may be spaced apart from each other at a cell boundary B between the adjacent standard cells.

Gate lines G1 and G2 may extend in a second direction D2 that is perpendicular to the first direction D1. The gate lines G1 and G2 may extend on the active pattern AC (e.g., the gate lines G1 and G2 may overlap the active pattern AC). The first gate line G1 may extend on the first active region AC1, and the second gate line G2 may extend on the second active region AC2. A respective source/drain region SD may be formed on one side of each of the gate lines G1 to G2 on the active pattern AC. In other words, a first source/drain region SD1 may be formed on one side of the first gate line G1 on the first active region AC1, and a second source/drain region may be formed on one side of the second gate line G2 on the second active region AC2. Conductive lines MW1 and MW2 may extend in the first direction D1 on a plane separated from the upper surfaces of the gate lines G1 to G2.

Lower surfaces of source/drain contacts CA1 and CA2 may be connected respectively to the source/drain regions SD1 and SD2, and upper surfaces thereof may be connected to respective source/drain vias LA1 and LA2. Lower surfaces of the source/drain vias LA1 and LA2 may be connected respectively to the upper surfaces of the source/drain contacts CA1 and CA2, and upper surfaces of the source/drain vias LA1 and LA2 may be connected respectively to the conductive lines MW1 and MW2.

Although it is not shown, the gate lines G1 to G2 may include a stacked structure of TiAlC/TiN/W, a stacked structure of TiN/TaN/TiAlC/TiN/W or a stacked structure of TiN/TaN/TiN/TiAlC/TiN/W, according to some example embodiments.

According to some example embodiments, the integrated circuit may include a plurality of conductive lines parallel to each other in the first direction D1, and source/drain contacts and gate contacts may be connected to at least one of the plurality of conductive lines. For example, as shown in FIG. 2, the conductive lines MW1 and MW2 may extend in the first direction D1, and the source/drain contacts CA1 and CA2 may be connected respectively to the conductive lines MW1 and MW2 by the source/drain vias LA1 and LA2.

As best seen in FIG. 2, a first standard cell CELL1 and a second standard cell CELL2 may be placed to face each other as adjacent cells on the basis of the cell boundary B. The first standard cell CELL1 may include the first active region AC1, the first gate line G1, the first source/drain region SD1, the first source/drain contact CAL the first source/drain via LA1, and the first conductive line MW1. The second standard cell CELL2 may include the second active region AC2, the second gate line G2, the second source/drain region SD2, the second source/drain contact CA2, the second source/drain via LA2, and the second conductive line MW2. For convenience of explanation, a distance from a tip of the conductive line MW1 of the standard cell CELL1 to the cell boundary B is assumed to be d1, and a distance from a tip of the conductive line MW2 of the standard cell CELL2 to the cell boundary B is assumed to be d2. Also, a distance from the tip of the conductive line MW1 of the standard cell CELL1 to the intersection of the conductive line MW1 with the source/drain via LA1 is assumed to be W1, and a distance from the tip of the conductive line MW2 of the standard cell CELL2 to the intersection of the conductive line MW2 with the source/drain via LA2 is assumed to be W2.

According to design rules for integrated circuit design, various rules, structures, and widths, lengths, heights, etc. of structures for place & routing may be specified.

The length, width, and height of the conductive line may also be defined in the design rules according to some example embodiments. As an example, a length of W1 and/or W2 may be previously set to a predetermined value. The predetermined value of the length W1 and/or W2 may be dependent on various factors, such as a spaced distance from the tip of the conductive line of the adjacent cell, the distance from the cell boundary, the cell structure below the conductive line, and the like.

With reference to steps S30, S40, and S50 of FIG. 1, after MW1 and MW2 on the same line in the process order considering the mask of step S40 are formed as a single conductive line, the conductive line between adjacent standard cells may be cut to a predetermined pattern C at the cell boundary B.

According to some example embodiments, when there is a cut pattern C between the conductive line and the conductive line on the adjacent same line, W1 of the conductive line may be set to be a relatively short length, and when there is no cut pattern C, W1 of the conductive line may be set to be a relatively long length. Considering the operation reliability of the integrated circuit, it is advantageous that W1 of the conductive line be set to be a long length or the relatively long length. However, as the integrated circuit process becomes finer, in principle, the design rule may be set to be as short of a length as possible (e.g., to a minimum length such that there is no problem in operation), and may be set to be long only in exceptional cases.

According to some example embodiments, at the time of generating a layout draft, when a spaced distance (measured from Tip to Tip, or d1+d2) between the tip of the conductive line MW1 of standard cell CELL1 and the tip of the conductive line MW2 of standard cell CELL2 is 24 nm, a cut pattern C between the conductive lines may be placed. That is, when the distance between each of the tips of the conductive lines MW1 and MW2 of the standard cells CELL1 and CELL2 and the cell boundary B is 12 nm, the length of the distances W1 and W2 from the tip of the respective conductive line MW1/MW2 to the intersection of the conductive line MW1/MW2 with the respective source/drain via LA1/LA2 may be defined, in principle, as a short length, e.g., 5 nm. As such, by satisfying the design rule conditions that take into consideration the design, potential process errors, and an influence on an adjacent cell according to the formation of the source/drain vias LA1/LA2, when checking whether the design rule of the final layout data is satisfied, no error occurs.

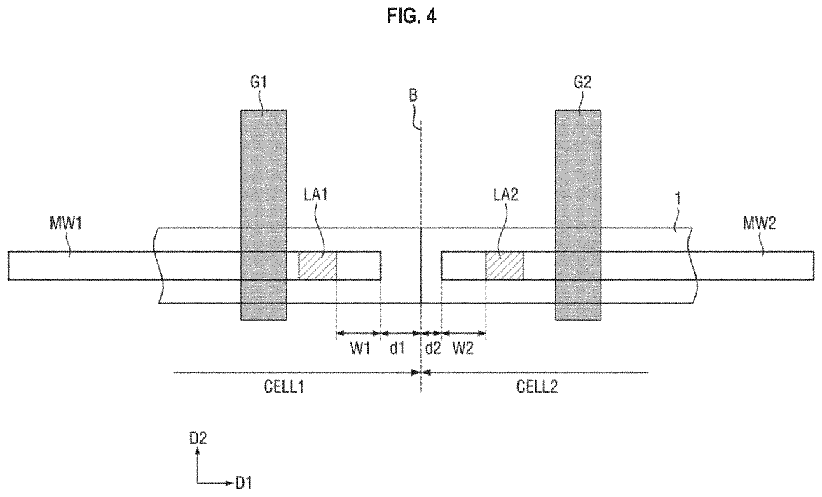

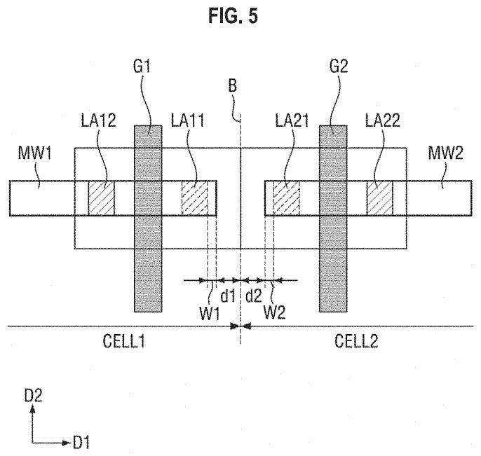

Incidentally, as shown, although the spaced distance (Tip to Tip, d1+d2) from the tip of the conductive line MW1 of the standard cell CELL1 to the tip of the conductive line MW2 of the standard cell CELL2 may be at least 24 nm, if the length of W1 and W2 is set as a length of 9 nm as an another example, the conductive line may too approach the conductive line of the adjacent cell on the basis of the cell boundary B. In this case, a problem may occur in the operation reliability of the integrated circuit, and an error may occur when checking whether the design rule of the final layout data is satisfied. Specifically, checking as to whether the design rule is satisfied will be explained in FIGS. 4 and 5.

FIGS. 4 and 5 show examples of layouts of the example integrated circuit according to some example embodiments.

In FIG. 4, the distance d1 from the tip of the conductive line MW1 of the standard cell CELL1 to the cell boundary B is assumed to be 52 nm, and the distance d2 from the tip of the conductive line MW2 of the standard cell CELL2 to the cell boundary B is assumed to be 12 nm. That is, the length of d1 is assumed to be longer than that d2.

In the shown example, since the length of d1 is relatively long, the tip of the conductive line MW2 may be able to further extend in the direction of the cell boundary B according to the exception of the design rule. That is, the length of W2 may be further elongated.

Incidentally, in the place & routing step (S30 of FIG. 1), when the length of W1 and W2 of the standard cell CELL1 and the standard cell CELL2 is each set to 5 nm only according to the principle of the design rule, an error may occur when checking whether the design rule of the final layout is satisfied.

In FIG. 5, the standard cell CELL1 may have a source/drain via LA11 and a source/drain via LA12 placed on both sides of the gate line G1, and may include a conductive line MW1 that extends in the first direction D1 and simultaneously connects the source/drain via LA11 and the source/drain via LA12. The standard cell CELL2 may have a source/drain via LA21 and a source/drain via LA22 placed on both sides of the gate line, and may include a conductive line MW2 that extends in the first direction D1 and simultaneously connects the source/drain via LA21 and the source/drain via LA22.

In this case, considering the design rule regulation of the length of W1 and W2 and the spaced distance (d1+d2) at the cell boundary B, when a space between the adjacent source/drain via LA11 and source/drain via LA21 becomes too narrow, a design rule error may occur when the source/drain via LA11 and the source/drain via LA21 are placed at the same time.

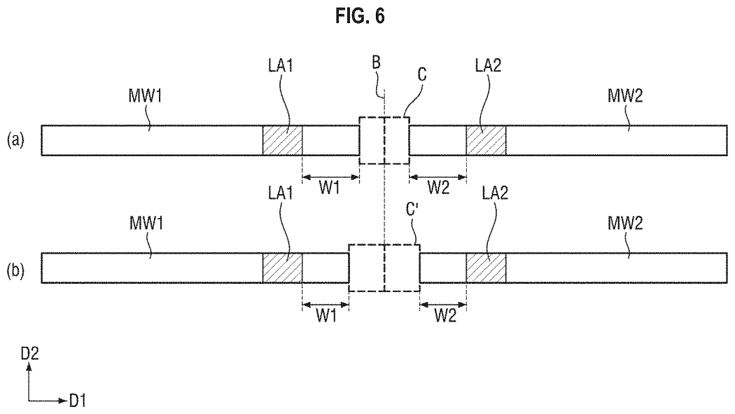

FIGS. 6 to 8 show examples of layouts of the example integrated circuit according to some example embodiments.

A description will be given with reference to FIGS. 6 to 8 to prevent or avoid occurrences of design rule errors and to improve operation reliability of integrated circuits. According to some example embodiments, the place & routing step (S30 of FIG. 1) of the integrated circuit first may generate a layout draft as a first place & routing step, and may modify and settle the layout as a second place & routing step after checking whether the design rules are satisfied.

Referring to FIG. 6, the conductive lines MW1 and MW2 may be first placed on the upper surfaces of the source/drain vias LA1 and LA2 according to some example embodiments. Subsequently, the conductive line may be cut by the cut pattern C on the basis of the cell boundary B, and may be separated into the conductive lines of the standard cell CELL1 and the standard cell CELL2. In this case, W1 of the conductive line MW1 and W2 of the conductive line MW2 of the layout draft may be cut by the cut pattern to a length according to the principle that is preset in the design rule. In the example shown, it is assumed that d1 and d2 are each 12 nm and W1 and W2 are placed at 5 nm.

Thereafter, it is possible to check whether the design rules are satisfied. For example, by checking the design rules of the cell boundary B region, it is possible to check whether the spaced distance (d1+d2) between the conductive lines is equal to or greater than a preset threshold value.

When the spaced distance is equal to or greater than a preset first threshold value (24 nm), the length of W1 and W2 is determined to satisfy the design rules, and the final layout may be settled as in the draft layout.

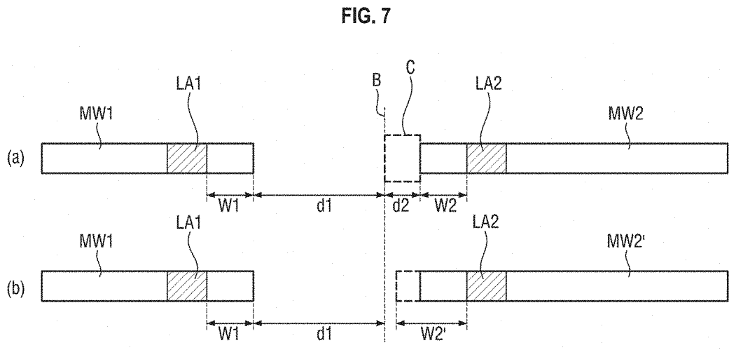

Referring to FIG. 7, the conductive lines MW1 and MW2 may be placed on the upper surfaces of the source/drain vias LA1 and LA2 according to some example embodiments. Subsequently, the cut pattern C of the conductive line may be formed on the basis of the source/drain vias LA1 and LA2.

W1 of the conductive line MW1 and W2 of the conductive line MW2 of the layout draft may be cut by a cut pattern to a length according to the principle that is preset in the design rules. In the shown example, W1 and W2 are assumed to be placed at 5 nm as an example.

Thereafter, it is possible to check whether the design rules are satisfied. For example, by checking the design rule of the cell boundary B region, it is possible to check whether the spaced distance (d1+d2) between the conductive lines is equal to or greater than a preset threshold value.

When the spaced distance is equal to or greater than the predetermined first threshold value (24 nm) and the distance of d1 is a second threshold value (52 nm), it is determined that the length (5 nm) of W2 does not satisfy the design rules, and the layout draft may be modified.

Since a distance of d1 is equal to or greater than the second threshold value, the layout draft may be modified so that the length of W2 extends according to the exception of the design rule. For example, the length of W2 may be extended from 5 nm to 9 nm.

The place & routing step may settle the final layout with the modified layout.

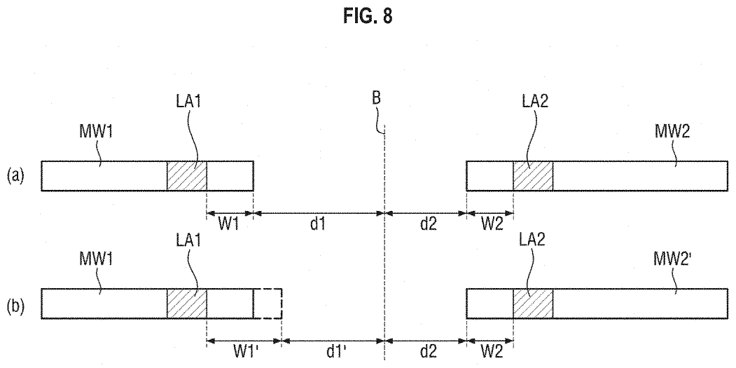

Referring to FIG. 8, the conductive lines MW1 and MW2 may be placed on the upper surfaces of the source/drain vias LA1 and LA2 according to some example embodiments. Subsequently, the cut pattern C of the conductive line may be formed on the basis of the source/drain vias LA1 and LA2.

W1 of the conductive line MW1 and W2 of the conductive line MW2 of the layout draft may be cut by a cut pattern to a length according to the principle that is preset in the design rules. In the shown example, W1 and W2 are assumed to be placed at 5 nm as an example.

Thereafter, it may be possible to check whether the design rules are satisfied. For example, by checking the design rules of the cell boundary B region, it is possible to confirm whether the spaced distance (d1+d2) between the conductive lines is equal to or greater than the preset threshold value.

If the spaced distance is equal to or greater than the predetermined first threshold value (24 nm) and the distance of d1 and d2 is equal to or greater than 52 nm, it is determined that the lengths of W1 and W2 do not satisfy the design rules, and the layout draft may be modified.

Since the distance of d1 is equal to or greater than the second threshold value, the layout draft may be modified so that the length of W1 or W2 extends according to the exception of the design rules. For example, the length of W1 may extend from 5 nm to 9 nm or more. In this case, a connecting fin for connection to another conductive line may be further placed on the extended conductive line W1′.

The place & routing step may settle the final layout with the changed layout.

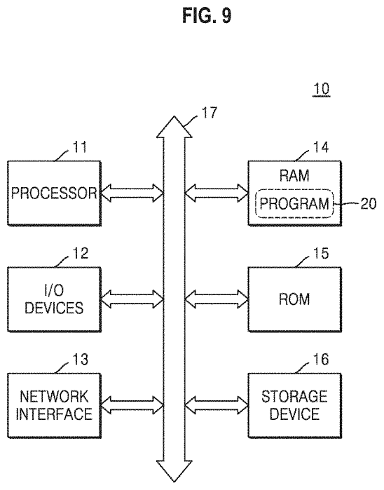

FIG. 9 is a block diagram showing a computing system including a memory that stores a program according to some embodiments.

At least some of the steps and operations involved in methods for fabricating the integrated circuits (e.g., the method shown and described with reference to FIGS. 1 to 8) according to some example embodiments may be performed in the computing system 10.

The computing system 10 may be a fixed computing system such as a desktop computer, a workstation, and a server, or may be a portable computing system such as a laptop computer. As shown in FIG. 9, the computing system 10 may include a processor 11, I/O devices 12, a network interface 13, a RAM (random access memory) 14, a ROM (read only memory) 15, and a storage device 16. The processor 11, the I/O devices 12, the network interface 13, the RAM, 14, the ROM 15 and the storage device 16 may be connected to the bus 17, and may communicate with each other through the bus 17.

The processor 11 may be called a processing unit, and may include at least one core capable of executing an arbitrary command set (e.g., IA-32 (Intel Architecture-32), 64-bit extension, IA-32, x86-64, PowerPC, Sparc, MIPS, ARM, IA-64, etc.) such as, for example, a micro-processor, an AP (application processor), a DSP (digital signal processor), and a GPU (graphic processing unit). For example, the processor 11 may access the memory, that is, the RAM 14 or the ROM 15, through the bus 17, and may execute commands stored in the RAM 14 or the ROM 15. As shown in FIG. 9, the RAM 14 may store a program 20 according to an exemplary embodiment of the present disclosure or at least a part thereof, and the program 20 may cause the processor 11 to perform at least some of the steps involved in the method for fabricating the integrated circuit. That is, the program 20 may include a plurality of commands capable of being executed by the processor 11, and the plurality of commands included in the program 2000 may cause the processor 11 to perform, for example, the logic synthesis operation of step S20 of FIG. 1 and/or the P&R (place & routing) operations of step S30.

The storage device 16 may be configured to retain or maintain stored data even if the power supplied to the computing system 10 is cut off. For example, the storage device 16 may include a non-volatile memory device, and may also include a storage medium such as a magnetic tape, an optical disk, and a magnetic disk. Also, the storage device 16 may also be attachable to and detachable from the computing system 10. The storage device 16 may also store the program 20 according to an exemplary embodiment of the present disclosure, and before the program 20 is executed by the processor 11, the program 20 or at least some thereof may be loaded into the RAM 14 from the storage device 16. Alternatively, the storage device 16 may store files written in a program language, and the program 20 generated by a compiler from the file or at least some thereof may be loaded into the RAM 14. Further, in some example embodiments, the storage device 16 may store a database (not shown in FIG. 9), and the database may include information necessary for designing an integrated circuit, for example, the standard cell library 1 of FIG. 1.

The storage device 16 may also store data to be processed by the processor 11 or data processed by the processor 11. That is, the processor 11 may generate data by processing the data stored in the storage device 16 according to the program 20, and may store the generated data in the storage device 16. For example, the storage device 16 may also store the RTL data S10, the netlist data 2 and/or the layout data 3.

The I/O devices 12 may include an input device such as a keyboard and a pointing device, and may include an output device such as a display device and a printer. For example, a user may trigger the execution of the program 20 by the processor 11 through the I/O devices 12, may input the RTL data S10 and/or the netlist data 2 of FIG. 1, and may confirm the layout data 3 of FIG. 1

The network interface 13 may provide an access to a network outside the computing system 10. For example, the network may include a plurality of computing systems and communication links, and the communication links may include wired links, optical links, wireless links or any other type of link.

In concluding the detailed description, those skilled in the art will appreciate that many variations and modifications may be made to the example embodiments disclosed herein without substantially departing from the principles of the present inventive concepts. Therefore, the disclosed example embodiments of the inventive concepts are used in a generic and descriptive sense only and not for purposes of limitation.

What is claimed is:

1. A layout method of an integrated circuit that includes a plurality of standard cells, the layout method comprising:
placing first and second standard cells selected from a standard cell library;
interconnecting the placed first and second standard cells to generate a layout draft;
confirming placement and routing at a cell boundary between the interconnected first and second standard cells; and
revising the layout draft as a result of the confirmation,
wherein each of the first and second standard cells includes:
an active region that extends in a first direction;
a gate line that extends in a second direction and that intersects the active region;
a source/drain region that extends in the second direction and placed on one side of the gate line to be spaced apart;
a source/drain via that is placed on the source/drain region; and
a conductive line that extends in the first direction and is interconnected to an adjacent standard cell through the source/drain via,
wherein confirming the placement and routing at the cell boundary between the interconnected first and second standard cells comprises comparing a first spaced distance from a tip of a first conductive line of the first standard cell to a tip of a second conductive line of the second standard cell across the cell boundary, and a second spaced distance from the tip of the conductive line of the first standard cell to the cell boundary with first and second preset threshold values, respectively, and
wherein revising the layout draft comprises adjusting a tip position of the tip of the second conductive line of the second standard cell.

2. The layout method of the integrated circuit of claim 1, wherein the first threshold value for the first spaced distance is 24 nm, and wherein the second threshold value for the second spaced distance is 52 nm.

3. The layout method of the integrated circuit of claim 2, wherein revising the layout draft comprises extending the second conductive line of the second standard cell when the first spaced distance is greater than the first threshold value.

4. The layout method of the integrated circuit of claim 2, wherein revising the layout draft comprises, when the first spaced distance is the first threshold value, and a distance from the tip of the first conductive line of the first standard cell to an intersection of the first conductive line of the first standard cell with the source/drain via of the first standard cell is a preset minimum distance, settling the layout draft as a final layout.

5. The layout method of the integrated circuit of claim 3, wherein the tip of the second conductive line of the second standard cell is extendable to a position at which the first spaced distance is equal to the first threshold value.

6. The layout method of the integrated circuit of claim 3, wherein when the distance from the tip of the second conductive line to the cell boundary is equal to or greater than the second threshold value,
the tip of the second conductive line of the second standard cell is extended by a preset extension length.

7. The layout method of the integrated circuit of claim 6, wherein in revising the layout draft comprises, when the length from the intersection with the source/drain via to the tip of the conductive line facing the cell boundary is 5 nm, extending the length from the intersection with the source/drain via to the tip of the conductive line facing the cell boundary to 9 nm.

8. A layout method of an integrated circuit, the layout method comprising:
placing a first standard cell and a second standard cell from a standard cell library on respective sides of a cell boundary;
placing a source/drain via and a conductive line on each of the first standard cell and the second standard cell;
measuring a first spaced distance between a tip of the conductive line of the first standard cell and measuring a second spaced distance between a tip of the conductive line of the second standard cell and the cell boundary;
adjusting a tip position of the tip of the conductive line of the first standard cell or a tip position of the tip of the conductive line of the second standard cell when the first spaced distance or the second spaced distance is equal to or greater than a preset threshold value; and
settling a layout of the conductive line having the adjusted tip position.

9. The layout method of the integrated circuit of claim 8, wherein each of the first standard cell and the second standard cell includes
an active region that extends in a first direction;
a gate line that extends in a second direction and that intersects the active region;
a source/drain region that extends in the second direction and is placed on one side of the gate line, wherein the source/drain region has an upper surface to which the source/drain via placed on the respective standard cell is connected, and
the conductive line placed on the respective standard cell, wherein the conductive line extends in the first direction, is connected to the upper surface of the source/drain via of the respective standard cell, and is interconnected to an adjacent standard cell.

10. The layout method of the integrated circuit of claim 9, wherein a length from the tip of one of the conductive lines facing the cell boundary between the first standard cell and the second standard cell to an intersection of the conductive line with the respective source/drain via is 5 nm or less.

11. The layout method of the integrated circuit of claim 10, wherein a first threshold value of the first spaced distance or the second spaced distance is at least 24 nm.

12. The layout method of the integrated circuit of claim 10, wherein adjusting the tip position comprises extending one of the conductive lines so that the length from the tip of the extended conductive line facing the cell boundary between the first standard cell and the second standard cell to the intersection of the conductive line with the respective source/drain via is at least 9 nm.

13. The layout method of the integrated circuit of claim 10, wherein the tip position of the conductive line of the first standard cell or the second standard cell is adjustable up to at least the threshold value of the first spaced distance or the second spaced distance.

14. An integrated circuit comprising:
a first standard cell and a second standard cell adjacent to each other in a first direction,
wherein the first standard cell comprises:
a first gate line that extends in a second direction;
a first source/drain region that extends in the second direction and is placed on one side of the first gate line;
a first source/drain via that is placed on the first source/drain region; and
a first conductive line that extends in the first direction and is placed to be connected to an upper surface of the first source/drain via,
wherein the second standard cell comprises:
a second gate line that extends in the second direction;
a second source/drain region that extends in the second direction and is placed between the second gate line and a cell boundary with the first standard cell;
a second source/drain via that is placed on the second source/drain region; and
a second conductive line that extends in the first direction and placed to be connected to an upper surface of the second source/drain via, and
wherein when a spaced distance between a tip of the first conductive line facing the cell boundary and a tip of the second conductive line facing the cell boundary is equal to or greater than a preset threshold value, a length in the first direction from the tip of the first conductive line to an intersection of the first conductive line with the first source/drain via has a length different from a preset first width.

15. The integrated circuit of claim 14, wherein the preset first width is a width which is preset by a design rule governing placement and routing of the first standard cell and the second standard cell.

16. The integrated circuit of claim 14, wherein a length in the first direction from the tip of the first conductive line to the intersection of the first conductive line with the first source/drain via is longer than the first width.

17. The integrated circuit of claim 14, wherein the threshold value is at least 24 nm.

18. The integrated circuit of claim 17, wherein when the distance from the tip of the first conductive line to the cell boundary is 52 nm or more, the length in the first direction from the tip of the second conductive line to the intersection of the second conductive line with the second source/drain via is an extended length greater than the first width.

19. The integrated circuit of claim 15, wherein the first width is 5 nm or less.

20. The integrated circuit of claim 16, wherein the length in the first direction from the tip of the first conductive line to the intersection of the first conductive line with the first source/drain via is at least 9 nm.
